(19) United States
(12) Patent Application Publication
(10) Pub. No.: US 2026/0358716 A1
(43) Pub. Date: Nov. 12, 2026

(54) METHOD OF GENERATING A PROJECTION PATTERN OF A PLURALITY OF PROJECTIONS OF A SUBSTRATE TABLE

(71) Applicant: ASML NETHERLANDS B.V., Veldhoven (NL)

(72) Inventors: Alexander STEIN, Berlin (DE); Ernst LEHBERGER, Berlin (DE)

(73) Assignee: ASML NETHERLANDS B.V., Veldhoven (NL)

(21) Appl. No.: 19/134,383

(22) PCT Filed: Nov. 20, 2023
(86) PCT No.: PCT/EP2023/082427

§ 371 Date: May 30, 2025

(30) Foreign Application Priority Data
Dec. 23, 2022 (EP) 22216358.6

(51) Int. Cl. G03F 7/00

(52) U.S. Cl. CPC G03F 7/70216

(57) ABSTRACT

A pattern of projections in a surface portion of a substrate table for supporting a wafer is generated by: providing repulsive periphery potentials acting in the support plane and including outer periphery potentials being assigned to outer periphery points surrounding the surface portion; providing an initial distribution of projections, each having a variable projection position in the surface portion; providing repulsive projection potentials acting in the support plane and being assigned to the projections; calculating a local force acting on each of the projections, based on a superposition of the periphery and projection potentials at the position of the projection; and generating the projection pattern to be obtained by repeatedly shifting the projection positions and calculating the local force acting on each of the projections at the current position, until a predetermined optimization criterion is fulfilled. Furthermore, a substrate table and manufacturing the substrate table are described.

### CROSS-REFERENCE TO RELATED APPLICATIONS

This application claims priority of EP application 22216358.6 which was filed on 23 Dec. 2022 and which is incorporated herein in its entirety by reference.

### FIELD OF THE INVENTION

The invention relates to a method for generating a projection pattern, in particular determining projection positions, of a plurality of projections of a substrate table for supporting a substrate, like a semiconductor wafer, in particular to a method of designing the arrangement of projections of a substrate table to be manufactured. Furthermore, the invention relates to a method of manufacturing the substrate table and to a substrate table. Applications of the invention are available e.g. in the design of substrate tables, like electrostatic clamps or vacuum clamps.

### TECHNICAL BACKGROUND

It is generally known that a substrate table, which is also referred to as a clamping apparatus, clamp, chuck, substrate support, substrate holder, wafer table or wafer board, has a plate-shaped base body to receive the substrate. The plate-shaped base body may be constructed as one single plate or in sandwiched form from multiple plates, and it is provided on at least one surface with protruding projections (also referred to as pins or burls). Plane front surfaces (or: upper surfaces, end faces) of the projections form a support plane for accommodating the substrate. The front surfaces define the support plane for the held component.

When operating the substrate table, the substrate is pressed against the support plane under the effect of a holding force. Depending on the type of holding force used, a clamp may be configured e.g. as an electrostatic clamp (ESC) or a vacuum clamp. Providing the support plane with high planarity and mechanical stability is essential for the application of the clamp, e.g. in handling semiconductor wafer in a lithography process. The front surfaces of the projections have to be aligned and an arrangement of the projections with high homogeneity is needed.

The arrangement of the projections (also referred to as projection pattern or projection map) is limited by an outer periphery (also referred to as outer contour) enclosing a surface portion, where the substrate is to be held. Furthermore, the projection pattern may include at least one interruption (part of the surface portion without a projection) created by at least one functional element (also referred to as feature) of the substrate table within the surface portion. Depending on the type of the functional element, the interruption may be a 0-dimensional gap (dot shape), a 1-dimensional gap (line shape) or a 2-dimensional gap (spot or area shape). Each functional element forms an inner periphery (also referred to as inner contour) of the surface portion.

Providing a projection pattern with a homogeneous distribution of the projections is challenging along the outer periphery and along the optional at least one inner periphery of the surface portion accommodating the substrate. In particular, the generation of projection patterns of clamps, e.g. for ESCs or wafer boards, with optimized flatness involves two problems: The first challenge is to determine flatness-optimized local projection patterns along sections of the outer periphery with complex geometry, such as corners or transitions from round to straight sections of periphery, and/or around functional elements, such as e-pins (or: lift pin holes) or notches. This is conventionally achieved via finite elements analysis and numerical optimization. However, due to the complexity of the task, this is limited to the smallest possible areas (only the immediate vicinity around e.g. a functional element). The second challenge is to integrate the individual local projection pattern(s) along section(s) of the outer periphery with complex geometry and/or around functional element(s) into an overall projection pattern for the complete surface portion and to adapt these patterns to each other. Based on conventional approaches, this is extremely difficult or even impossible, especially for closely spaced features.

In conventional practice, a first approach of generating a projection pattern comprises manually arranging projections, based on visual consideration and intuition of a designer. This concept has substantial disadvantages in terms of required time and limited reliability. Secondly, a known software-based approach of designing a projection arrangement comprises the steps of creating an initial projection pattern (typically a circular pattern, using script language) with predefined projection spacing, which contains only the outer periphery and possibly a separation of the surface portion into two electrode segments, subsequent cutting out the location of functional elements, like nubs at or in nub-free features (e.g. e-pins), mostly by hand, and finally fitting the area between local pattern at the functional elements to the overall projection pattern (by script).

As a main disadvantage, fitting the local pattern(s) is very complex and takes a lot of time, e.g. up to one month, especially if there are plural functional elements. In particular, the spatial proximity of functional elements quickly brings this approach to its limits, since each local pattern is generated independently and there must be enough space for transition areas. As a further limitation, fitting the local patterns is limited to using the given initial projection pattern which possibly is not optimized for a given geometry and arrangement of functional elements and/or outer periphery.

### OBJECTIVE OF THE INVENTION

It is an objective of the invention to provide an improved method for generating a projection pattern of a plurality of projections of a substrate table for supporting a substrate, like a semiconductor wafer, wherein the method is capable of avoiding limitations or disadvantages of conventional techniques. In particular, the method is to be capable of generating the projection pattern in a substrate table to be manufactured with improved homogeneity, less time-consumption, with improved ability of adapting the projection arrangement to the geometry of the substrate table to be manufactured and optional functional element(s) thereof, and/or with reduced or even without dependence on manual, experience-based design decisions of a designer. It is a further objective of the invention to provide an improved method of manufacturing a substrate table for holding a substrate, in particular a semiconductor wafer, and/or an improved substrate table being capable of avoiding limitations or disadvantages of conventional techniques.

### SUMMARY OF THE INVENTION

These objectives are solved by a method for generating a projection pattern of a plurality of projections of a substrate table, a method of manufacturing a substrate table and/or a substrate table comprising the features of the independent claims. Advantageous embodiments and applications of the invention are defined in the dependent claims.

According to a first general aspect of the invention, the above objective is solved by a method of generating a projection pattern of a plurality of projections of a substrate table being configured for supporting a substrate, in particular a semiconductor wafer, in a surface portion of the substrate table, wherein end faces of the projections define a support plane (or: holding plane, plane of the surface portion) and the surface portion is surrounded by a plurality of outer periphery points within the support plane.

The projections comprise protrusions on a surface of the substrate table. The projections have plane end faces and e.g. a cylindrical or cubic shape. Preferably, all projections have the same shape and size. The cross-sectional dimension of the projections, e.g. the diameter thereof, preferably is negligibly small in comparison with the planar dimension of the surface portion. The projections may be considered as points or tips, and the position of each projection is provided by the location of the centre of the projection cross sectional area in the surface portion. The projections are arranged with spacings from each other. Generating the projection pattern (pattern of projection positions) in particular comprises determining the projection positions of a projection arrangement of a substrate table to be manufactured. The surface portion comprises a part of a substrate table surface where the substrate is to be supported by the projections.

The outer periphery points, in particular the positions thereof, are input parameters of the method of generating the projection pattern, and they comprise predetermined locations on the surface of the substrate table to be designed. The outer periphery points are positioned at fixed locations around the surface portion. The term “outer” refers to the fact that the projections of the surface portion are arranged within a closed line along all successive outer periphery points.

According to the invention, the method comprises providing a plurality of two-dimensional repulsive periphery potentials acting in the support plane. The periphery potentials comprise outer periphery potentials, each being assigned to one of the outer periphery points and represented by an outer periphery potential function fo(r), with r being a radial distance from the outer periphery point. The outer periphery potentials are further input parameters of the method of generating the projection pattern. Accordingly, each outer periphery point is considered to have a location and an associated outer periphery potential, which is a function with rotation symmetry within the support plane and with an amplitude decreasing with a distance from the outer periphery point considered.

According to the invention, the method further comprises providing an initial distribution of a plurality of projections, each having an initially variable projection position in the surface portion. Furthermore, a plurality of two-dimensional repulsive projection potentials is provided which act in the support plane, wherein each of the projection potentials is assigned to one of the projections and wherein, for each of the projections, the assigned projection potential is represented by a projection potential function fp(r), with r being a radial distance from the projection. The projection potentials are further input parameters of the method of generating the projection pattern. Again, each projection potential preferably is a function with rotation symmetry within the plane of the surface portion and with an amplitude decreasing with a distance from the projection.

Preferably, the initial projection distribution does not cover the complete surface portion where the projections are to be arranged, but one or more sections thereof only. Accordingly, the projections of the initial projection distribution have a local density, which is greater than a global density of the projection arrangement to be obtained. At the starting point of the method of generating the projection pattern, the initial projection distribution is more dense then the final projection arrangement, thus advantageously allowing to fill in the projections into the area of the surface portion. After completing the generating of the projection pattern, the distribution of projections has a lower global density within the area of the surface portion.

According to the invention, the method further comprises calculating a local force acting on each of the projections, wherein each local force is calculated based on a superposition of the periphery potentials and the projection potentials, in particular based on a superposition of spatial gradients thereof, at the projection position of the projection considered. The local force acting on a considered projection is a resulting force (vector sum) of partial forces between the projection considered and each of the other projections and the outer periphery points. Each partial force is calculated as a force acting in a pairwise superimposed potential of the projection considered and one of the other projections or outer periphery points, i.e. based on a gradient in the pairwise superimposed potential. As an example, if the periphery potentials and the projection potentials are proportional to 1/r, like the potential of an electrical charge, the partial forces are calculated like repulsive forces between electrical charges, represented by the projections.

An effective range of the periphery potential and the projection potentials depends on the potential shape, in particular the slope of the distance dependency thereof. Basically, all outer periphery potentials and all projection potentials may influence the local force on each considered projection. In practice, only closely-adjacent periphery points or projections, in particular the nearest neighbours of a considered projection determine the local force acting on the projection considered.

Furthermore, according to the invention, the projection pattern to be obtained is generated by repeatedly step-wise shifting the projection positions by position shifting increments and calculating the local force acting on each of the projections at the current projection position, until a predetermined optimization criterion is fulfilled. The optimization criterion generally is given by at least one predefined parameter which is characteristic for the homogeneity of the distribution of the projections. The inventors have found, that at least one parameter of varying the projection positions can be employed as the optimization criterion.

In particular, the projection positions are varied and the local force acting on each of the projections at the varied projection position is calculated. If the optimization criterion is fulfilled, the variation is stopped and the current projection pattern is the projection pattern to be obtained. If the optimization criterion is not fulfilled, the variation is continued. Thus, the projection pattern to be obtained is generated by an iteration process, during which the projection positions are varied and the local forces are determined, wherein the iteration process is completed when the optimization criterion is fulfilled. The optimization criterion may be tested after each variation of a single projection position or a sub-group of all projection positions. Preferably, the optimization criterion may be tested after the variation of all projection positions, i.e. all projection positions are shifted by position shifting increments in each iteration loop, and subsequently it is tested, whether the optimization criterion is fulfilled.

The position shifting increment includes a shifting direction within the support plane and an amount of position shifting increment. Preferably, the shifting direction of a projection considered is opposite to a direction of a net potential obtained from the superposition of the periphery potentials and the projection potentials at the projection position of the projection considered. The amount of position shifting increment may be constant during the whole iteration process, or it may be varied in dependence of the convergence of the iteration process.

Preferably, the step-wise shifting the projection positions may be executed with a position shifting increment, which depends on an amplitude of an overall potential per projection. The initially used increment may be relatively large, e.g. in range from 500 μm to 1500 μm, and the position shifting increment of varying the projection positions may decrease with approaching the optimized projection arrangement, e.g. down to a range from 5 μm to 20 μm. Advantageously, employing stepwise decreasing increments accelerates the process of finding the optimized projection arrangement.

According to a second general aspect of the invention, the above objective is solved by a method of manufacturing a substrate table being configured for holding a substrate, in particular a semiconductor wafer, comprising the steps of creating the pattern of projection positions of projections of the substrate table with the method according to the above first general aspect of the invention or an embodiment thereof, and manufacturing the projections on the substrate table at the positions provided by the pattern of projection positions. Manufacturing the projections on the substrate table can be executed by an additive or subtractive process as known from conventional techniques.

According to a third general aspect of the invention, the above objective is solved by a substrate table being configured for holding a substrate, in particular a semiconductor wafer, and comprising a plurality of projections, wherein end faces of the projections define a support plane for holding the substrate in a surface portion of the substrate table, wherein the projections are arranged according to a projection pattern of projection positions, which is generated by the method according to the above first general aspect of the invention or an embodiment thereof. Preferably, the substrate table is manufactured with the method according to the above second general aspect of the invention or an embodiment thereof. Preferably, the pattern of projection positions of most of the projections is matched to a hexagonal pattern. In particular, the pattern of projection positions comprises multiple hexagonal sub-patterns (hexagonal domains).

Further independent aspects of the invention comprise an apparatus for data processing (in particular a projection pattern generator), comprising a computer device which is configured for executing the method according to the above first general aspect of the invention or an embodiment thereof, and a computer program product, comprising instructions, which cause a computer, when processing the program, to execute the method according to the above first general aspect of the invention or an embodiment thereof.

The invention is based on the concept of treating the projections as repulsive point charges and letting them self-distribute in dependence of the mutual interactions within the potentials of the outer periphery points (and optionally inner periphery points, as introduced below). The inventive iterative design process uses self-organization of the projections to create the projection pattern: There is no need to distribute the projections by a designer, but the projections distribute themselves by stepwise varying the projection positions and calculating the local forces, while they are kept within the allowed surface portion by a given frame (outer periphery and optionally at least one inner functional element, as introduced below). Advantageously, this distribution automatically provides a most even distribution of the projections. As a further substantial advantage, the inventive method takes only a small fraction of time required for designing a projection arrangement in prior art, e.g. less than 10 hours, in particular down to 3 hours.

Advantageously, the projection pattern to be obtained is generated with extremely low effort for the designer and at the same time with maximum flexibility regarding geometry (shape of outer periphery and optionally number and shape of inner functional elements or disturbances).

Preferably, all outer periphery points of the outer periphery may have the same outer periphery potential. Alternatively, the outer periphery potentials may vary along the line of outer periphery points. With the latter embodiment, advantages in terms of adapting the projection arrangement to particular geometrical features of the outer periphery and/or parts thereof can be obtained. The same or different potentials may be kept constant during the whole design process, or they may be varied in the course of the design process.

According to a preferred embodiment of the invention, each of the outer periphery points is represented by an outer periphery projection with a fixed position. The outer periphery projections comprise a last outer row of projections surrounding the substrate portion and providing the outer periphery. Advantageously, available knowledge about an optimal position of the last outer row of projections can be directly incorporated into the inventive method. The fixed positions of the outer periphery projections can be obtained through general simulations or experiments or by the design of the substrate table.

According to a particularly advantageous embodiment of the invention, the surface portion includes at least one inner functional element surrounded by a plurality of inner periphery points, and the periphery potentials further comprise inner periphery potentials, each being assigned to one of the inner periphery points and represented by an inner periphery potential function fi(r), with r being a radial distance from the inner periphery point. Advantageously, the inner periphery potentials just provide further periphery potentials which are taken into account in calculating the local force acting on the projections. The inventive method allows the integration of the at least one inner functional element into the generation of the projection pattern. Furthermore, due to the inventive self-organizing approach, local areas of two adjacent features can be extremely close to each other, since the whole pattern is a “transition zone”.

Each potential of an inner periphery point, i.e. each inner periphery potential, preferably is a function with rotation symmetry within the plane of the surface portion and with an amplitude decreasing with a distance from the inner periphery point considered. The term “inner” refers to the fact that the at least one inner functional element defines a closed shape within the surface portion with a distance from the outer periphery. Preferably, the at least one inner functional element is free of projections.

With this preferred embodiment, the at least one inner functional element, in particular the position and size thereof, and the outer periphery points, in particular the positions thereof, may be given features of the substrate table to be designed, i.e. they are positioned at fixed locations within and/or around the surface portion. The inner periphery points are pre-defined around the at least one inner functional element. An inner line serially connecting the inner periphery points of an inner functional element completely encloses the inner functional element within the surface portion of the substrate table. The inner line may be considered as an inner periphery of the projection arrangement. The inner periphery points, in particular the positions thereof, are further input parameters of the method of generating the projection pattern, and they comprise predetermined locations on the surface of the substrate table to be designed. The inner periphery points are positioned at fixed locations around the at least one inner functional element.

Preferably, all inner periphery points may have the same inner periphery potential, or the inner periphery potentials may vary along the line serially connecting the inner periphery points. Accordingly, advantages for adapting the projection arrangement to at least one particular inner functional element and/or part thereof can be obtained. Like with the outer periphery points, the same or different potentials may be kept constant during the whole design process, or they may be varied in the course of the design process.

Preferably, each of the inner periphery points is represented by an inner periphery projection with a fixed position. Accordingly, the inner periphery projections preferably comprise a last row of projections surrounding the at least one inner functional element and providing the inner periphery. Like with the outer periphery projections, available knowledge about an optimal position of the last outer row of projections can be directly incorporated into the inventive method. The fixed positions of the inner periphery projections can be obtained through general simulations or experiments or by the design of the at least one inner functional element. Advantageously, the projections providing the inner periphery boundaries can be used directly in the generation of the overall pattern as parameters. As a further advantage, the inventive method may also distribute further patterns of already existing patterns (e.g. glue pads between projections).

A further advantage of the invention results from the fact that it may be employed with different types of inner functional elements, comprising e.g. at least one of a dot shaped gap, a line shaped gap and an area shaped gap in the arrangement of projections. A dot shaped inner functional element may comprise e.g. a small holes of size of projection pitch, like a gas inlet. A line shaped inner functional element may comprise e.g. a separation line of functional areas, e.g. electrodes on a bi-polar electrostatic chuck. An area shaped functional element has an area much bigger than a projection pitch (e.g., lift pin holes, cut outs for fork lifter, etc.).

According to a further preferred embodiment of the invention, the local force acting on each projection may be determined by a linear superposition of the periphery potentials and the projection potentials at the projection position of the projection considered. The linear superposition has advantages in terms of easy and fast calculation and obtaining a fast convergence of finding the optimized pattern of projections.

Advantageously, various optimization criteria are available for testing the homogeneity of the distribution of the projections. According to a first variant, the optimization criterion is determined by a sum of the local forces acting on the projections, and the step of shifting the projection positions is executed until the projection pattern is created, at which the sum of the local forces acting on the projections is minimized, in particular zero. Advantageously, with a minimized, in particular vanishing sum of the local forces acting on all projections, the positions of all projections are evenly distributed within the surface portion.

Alternatively or in addition, according to a second variant, the position shifting increments can be varied, in particular reduced, during the step-wise shifting of the projection positions, and the optimization criterion may be determined by a sum of all current position shifting increments, and the step of shifting the projection positions is executed until the sum of all current position shifting increments is below a predetermined threshold, particularly preferred zero. Advantageously, the position shifting increments easily can be tested during iterative generation of the projection pattern to be obtained.

If steps of analysing a convergence of the projection positions by a statistical analysis of averaged distances of the projections and a variance of the averaged distances of the projections are provided according to a further preferred embodiment of the invention, advantages in terms of setting an appropriate position shifting increment in varying the projection positions are obtained.

Advantageously, the step of varying the projection positions may be executed with a position shifting increment, which depends on the convergence of the projection positions. With improving the convergence, the position shifting increment can be reduced. Alternatively or in addition, the periphery potentials, i.e. the outer periphery potentials and/or the optional inner periphery potentials, may be varied in the course of the design process. In particular, the periphery potentials may be adjusted in dependence of the convergence of the projection positions.

Particularly preferred, the periphery potentials and the projection potentials are represented by potential functions f(r) proportional to 1/rp, with p being an uneven number selected in a range from 1 to 11. With the parameter p approaching 1, the potentials have a relatively large range and the local forces are relatively weak, while a parameter p increased towards 12 results in a relatively short potential range and relatively strong local forces. Accordingly, a lower parameter p is preferably employed with embodiments using inner functional elements with large distances, while a larger parameter p is preferably employed with embodiments using inner functional elements with small distances.

According to further preferred variants of the invention, the number of projections may be changed during the step-wise shifting of the projection positions, in particular at pre-selected local positions. Changing the number of projections may comprise increasing and/or reducing the complete number of projections. For example, a first phase of generating a projection pattern can be executed with less projections than a second phase of generating the projection pattern (and finding the optimized projection pattern). With another example, the number of projections can be locally reduced in the course of generating the projection pattern, e.g. at certain geometric features. Advantageously, the required computing processing power can be reduced and/or the convergence of the process can be improved with these embodiments.

### BRIEF DESCRIPTION OF THE DRAWINGS

Further advantages and details of the invention are described in the following with reference to the attached drawings, which schematically show in:

FIG. 1: a flowchart of a method for generating a projection pattern according to embodiments of the invention;

FIGS. 2 and 3: illustrations of the distribution of projections during the process of FIG. 1; and

FIG. 4: a flowchart of a method for manufacturing a substrate table, including the method of determining projection positions of FIG. 1.

### DETAILED DESCRIPTION OF PREFERRED EMBODIMENTS OF THE INVENTION

Features of embodiments of the invention are described in the following with particular reference to the generation of the projection pattern of a substrate table. The invention preferably is implemented with an ESC, a vacuum chuck or another clamp as it is known per se. Accordingly, details of the substrate table and the operation thereof are not described as they are known from prior art. It is noted that the figures include schematic illustrations only. In practice, the substrate table may have e.g. a circle shaped surface portion with about 100 to 50.000 projections, each with a diameter in a range from e.g. 10 μm to 10 mm. Reference is made to embodiments employing a substrate table with multiple inner functional elements. The invention is not restricted to these embodiments, but also can be implemented with a substrate table without an inner functional element.

The inventive method of generating a projection pattern can be implemented e.g. with a scripting language, like “GNU Octave” (Matlab clone) or with an Assembler software. Input parameters of the method of generating the projection pattern, like e.g. the fixed positions of the outer and optional inner periphery points, the periphery potential of each of the outer and optional inner periphery points, the projections potentials of the projections considered to be movable during pattern generation, the position shifting increments and the optimization criterion tested are selected based on numerical simulations, reference applications and/or geometric properties of the substrate portion considered.

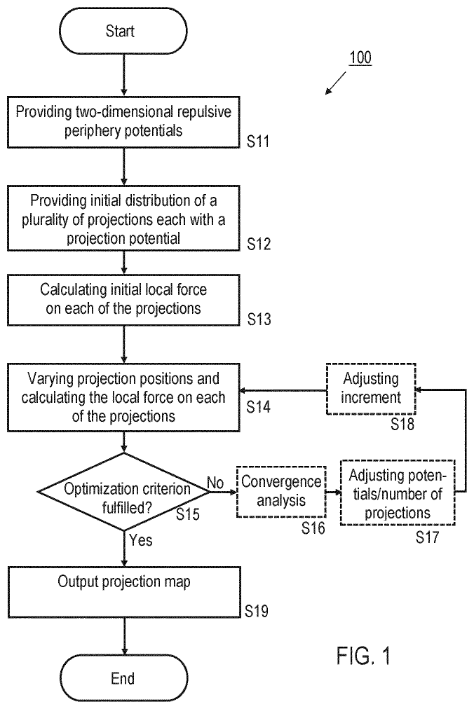

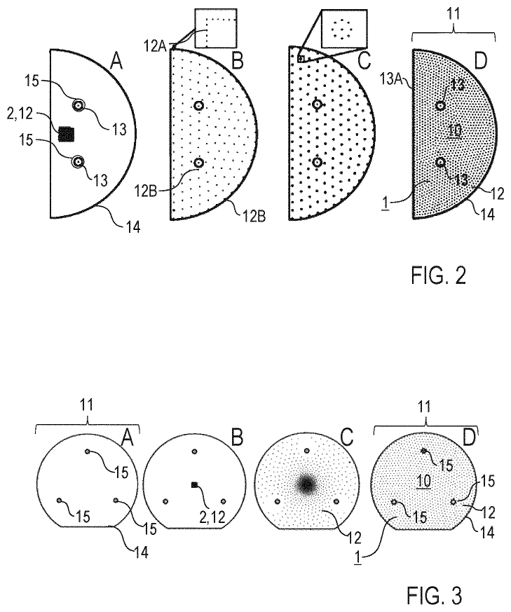

FIG. 1 schematically illustrates an embodiment of the method 100 of generating a projection pattern of a plurality of projections of a substrate table, as schematically shown in FIGS. 2 and 3.

FIGS. 2 and 3 illustrate the ESC's during different phases of the projection pattern generating method 100. As a first example, FIG. 2 shows a half of a bipolar ESC, wherein the substrate table 10 of the complete bipolar ESC has a circular surface portion 11 with one D-shaped electrode (semi-circular electrode, not shown) in each half of the surface portion 11. As another example, the substrate table 10 of FIG. 3 comprises a monopolar ESC with a surface portion 11 having the shape of a circular section.

The substrate table 10 (partially shown in FIGS. 2D and 3D) with a projection pattern 1 to be generated has the surface portion 11 with a plurality of projections 12 and multiple inner functional elements 13. End faces of the projections 12 within the surface portion 11 define a support plane (parallel to the drawing plane) for supporting a substrate, e.g., silicon wafer (not shown). An outer periphery 14 surrounds the surface portion 11 within the support plane. The outer periphery 14 is defined by a line serially connecting outer periphery points, to which outer periphery potentials are assigned as described below. Preferably, the outer periphery points are preset fixed outer periphery projections, i.e. the outer periphery 14 is provided by a line serially connecting the last outer row of projections (see e.g. outer periphery projection 12A in FIG. 2B). Optionally, additional preset outer periphery points (not shown in detail) between the projections 12B may be provided along the outer periphery 14.

The outer periphery 14 is provided as a restriction of the surface portion 11 and for obtaining a convergence of the iterative projection pattern generating method 100. The outer periphery 14 creates a repulsive frame, wherein the projections 12 are kept in the allowed area defined by the repulsive frame. The repulsive frame consists of a translation of an outer contour of the surface portion 11 into points (point charges). By choosing the mutual spacing of neighbouring point charges, an optimum of computation time (number of outer periphery points in addition to the projections) and rasterization of the last row of projections can be achieved. In addition, the potential of the outer projections and optionally further periphery points at the outer periphery 14 (area boundary) can be changed with respect to the potential of the variable projections 12 in such a way that the distance of the last row of projections to the outer periphery 14 can be adjusted. In this way, the distance of the projections 12 closest to the repulsive frame (boundary of the allowed area) can be freely selected and thus the flatness at the periphery can be adjusted.

The schematically shown inner functional elements 13 (see FIG. 2) comprise e.g. 0-dimensional features, like a small hole for a gas inlet, and/or 2-dimensional point-or spot-shaped features, like lift pin holes. In case of FIG. 2, an electrical insulation line between the semi-circular electrodes can be considered as a 1-dimensional line-shaped inner functional element 13A (see FIG. 2D).

Each inner functional element 13 is considered to be surrounded by a line along a plurality of preset inner periphery points (not shown in detail) defining an inner periphery 15. The inner periphery points are provided for defining the inner periphery potentials. Preferably, the inner periphery points of an inner functional element 13 are considered to be provided by a given group of nearest fixed projections 12B surrounding the inner functional element 13, i.e. the last row of projections 12B (e.g. as shown in FIG. 2B for illustrative purposes) surrounding the inner functional element 13.

Referring to FIG. 1, the projection pattern generating method 100 comprises a first step S11 of providing two-dimensional repulsive periphery potentials, wherein each periphery potential is assigned to one of the projections 12A, optionally to the additional outer periphery points, at the outer periphery 14 of the surface portion 11, or to one of the projections 12B surrounding the inner functional elements 13 at the inner peripheries 15 of the surface portion 11. The projections 12A, 12B at the outer and inner peripheries 14, 15 and optionally the additional outer periphery points have fixed positions. The fixed positions are obtained e.g. from a memory storing geometrical data of the substrate table 10 to be designed and/or by collecting and processing an image of the surface portion 11 of the substrate table 10 to be designed (e.g. according to FIG. 3A).

The outer or inner repulsive periphery potentials fo/fi are represented e.g. by the following equation:

f(r)=1/r (1)

Accordingly, all periphery potentials are equal. Alternatively, for further flexibility and improvement of the possible flatness, even several factors and/or functions of r can be introduced for the inner and outer periphery potentials and/or within each group of inner and/or outer periphery potentials. Advantageously, this allows to account for the different mechanical behavior of a held silicon wafer at the outer periphery and at inner features.

Subsequently, with step S12, an initial distribution 2 of a plurality of projections 12 is created, wherein each of the projections 12 of the initial distribution 2 has a repulsive projection potential fp and a variable projection position in the surface portion 11. Examples of initial distributions 2 are illustrated in FIGS. 2A and 3B. The number of projections of the initial distribution 2 may be equal to the whole number of projections 12 to be arranged. Alternatively, a smaller number of projections, e.g. by a factor of 3 to 9, can be set as the initial distribution 2. As an example, the initial distribution 2 may comprise 6000 to 9000 projections.

The projection potential fp assigned to each of the projection 12 is represented by equation (1) as well. Thus, the projections 12 are treated similarly to equal electric point charges and thus repel each other. However, the repulsive projection potential may also differ from the field of the point charge, e.g. in extension to the electric field with about 1/r to e.g. about 1/r5, to achieve special effects, e.g. in terms of homogeneity or projection density. The periphery and projection potentials may be equal or different. All projection potentials may be equal, or the projection potentials of different projections may be different.

According to the subsequent step S13, an initial local force F acting on each of the projections 12 is calculated, wherein the local force is determined by a superposition of the inner and outer periphery potentials and the projection potentials at the projection position of each considered projection 12. The inner and outer periphery potentials and the projection potentials are represented by potential functions according to equation (1). The local force F in the field is calculated e.g. according to the following equation:

Fⱼ=Σₖ₌₁aₖ*∇fᵢ(r)+Σₗ₌₁bₗ*∇fₒ(r)+Σₘ₌₁cₘ*∇fₚ(r) (2)

with the inner periphery potentials fi, the outer periphery potentials fo and the projection potentials fp. The force Fj on projection j is based on the superposition of all fixed (periphery) projections k, 1 and all “moveable” projections m. The weighting factors a, b and c (positive numbers) are chosen for easiest convergence. r is the distance of each of the fixed or movable projections to projection j. As a result of step S13, a local force is assigned to each of the projections 12 of the initial distribution 2.

With the further process, the projection positions of all projections 12 are varied and the local force on each of the projections 12 at the new positions is calculated with equation (2) (step S14). Varying the projection positions means displacing the projections 12 with a certain position shifting increment, including a direction and certain amount of position shifting increment. The direction of the displacement within the support plane may be obtained from the superposition of the potentials at the current projection position. The superimposed potentials represent a certain effective field (net field) with the direction depending on the sum of the potentials. The displacement is executed with a direction opposite to the direction of this effective field (or: opposite to the direction of the effective force). The amount of position shifting increment of displacement is selected in dependence of the phase of the iteration process in the method 100. At the beginning, the amount of position shifting increment is for instance 100 μm, and with a later phase of the process, the amount of position shifting increment can be adjusted to be lower, for instance 10 μm, see step S18, below.

The amount of position shifting increment may be obtained by an interpolation of a required step size for a selected projection 12 (considered as a point charge) by the cumulative total potential acting on it from all other projections 12 and a reasonable limitation of this step size. Preferably, the amount of position shifting increment of a projection 12 is proportional to the distance, which results, if one extrapolates the movement linearly on the basis of a current gradient of the net potential in such a way that the force becomes zero. Reducing the amount of position shifting increment with step S18 results in a “cooling down” of the motion of the projections 12 to reach convergence with progressive iterations. This means for instance a gradual limitation of the possible amount of position shifting increment per iteration.

Subsequently, after calculating the local forces acting on all projections 12, it is tested with step S15 whether a predetermined optimization criterion is fulfilled by the new projection positions and local forces on each of the projections 12. As an example, the sum of the local forces of all projections 12 is calculated. The sum of the local forces is compared with a predetermined threshold value, which provides the optimization criterion. The threshold value is for instance a residual local force sum or even 0.

If step S15 yields that the optimization criterion is not fulfilled, the process returns back to step S14. Again, the projection positions are varied and the local force on each of the projections 12 is calculated, followed by testing the optimization criterion.

Various steps may be included before returning to step S14, as illustrated with optional steps S16, S17 and S18. These optional steps S16 to S18 may be provided alone or in combination. For instance, the potentials and/or the amounts of position shifting increment can be adjusted on the basis of a predetermined reference information. In particular, the amount of position shifting increment may be reduced with step S18 when the difference between the current sum of the local forces and the optimization criterion is below a predetermined limit.

Alternatively or in addition, a convergence analysis can be included with step S16. The convergence analysis includes a statistical analysis of the variations of the local forces, for instance during the current iteration step or in consideration of multiple previous steps.

For the estimation of the result and the extremely efficient parameter selection (e.g. for the repulsion potentials of the periphery points) a real-time statistic may be implemented with step S16, so that e.g. the mean distance of the projections 12 (measured value for a desired target distance of the pattern) as well as e.g. the variance of this distance (homogeneity of the pattern) is known during the calculation and thus the convergence can be evaluated by the user.

With the progress of the iteration process, the projection number can be increased with step S17, in particular in dependence of the result of the convergence analysis of step S16. Furthermore, periphery and/or projection potentials may be adjusted with step S17. Increasing the number of projections 12 is schematically illustrated in FIG. 2C (see enlarged insert). A single projection 12 is replaced by an arrangement of e.g. 9 projections 12 as shown in FIG. 2C. The further process of varying projection positions and calculating the local force on each of the projections 12 is continued with the enlarged number of projections 12, until the optimization criterion is fulfilled.

Starting with a reduced projection number and increasing the projection number to the quantity required by the substrate table 10 with step S17 has substantial advantages for reducing the processing power. Due to the inventive technique, a large amount of computations are executed together, e.g. 30.000 real projections 12 and sometimes a similar number of periphery points. For reducing the processing time, e.g. to some minutes, the projection number is increased with step S17 after a stable distribution state is reached only. Reaching the stable state may be found as a result of the convergence analysis S16 or by an analysis of a current maximum increment. Thus, only a minimal total motion is required for the complete set of projections 12, so that the computation time is minimized.

This iterative algorithm is run until the positions do not change within a certain range. This inventive approach allows an automatic equal distribution of the projections 12 in the surface portion 11. Accordingly, if step S15 yields that the optimization criterion is fulfilled, the arrangement of the projections 12 at the current projection positions is considered as the projection pattern to be generated, and the projection pattern is output as a projection map with step S19. Usually, the application of the inventive method 100 yields projection pattern matched to a hexagonal projection pattern, including domain boundaries as shown e.g. in FIG. 2D. Thus, the projection pattern generation method 100 is completed.

FIGS. 3A to 3D further illustrate the execution of the projection pattern generation method 100, which is possible for a usual monopolar ESC within some minutes. FIG. 3A shows the provision of the outer and inner peripheries 14, 15 of the surface portion 11 (step S11). The injection of the projections 12 (point charges in the support plane) as an initial distribution 2 is illustrated in FIG. 3B. As a result of the projection position variation and local force calculation on each of the projections 12, the projections 12 are step-wise distributed between the outer and inner peripheries as schematically illustrated in FIG. 3C. Just before or after reaching the homogeneous distribution of the projections 12, the potentials may be adjusted for obtaining an optimized distance of the projections 12 to the outer periphery 14, as schematically illustrated in FIG. 3D.

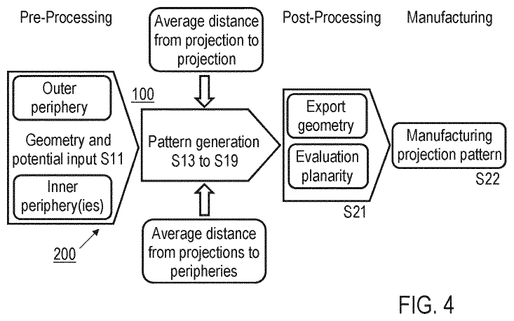

FIG. 4 schematically illustrates an embodiment of the method 200 of manufacturing a substrate table, in particular manufacturing the projection pattern of the substrate table. The manufacturing method 200 includes pre-processing steps, comprising the method 100 of generating the projection pattern, as shown in FIG. 1. Accordingly, the geometry, including the inner and outer peripheries, and the assigned inner and outer periphery potentials are input with step S11. After providing initial distribution of a plurality of projections including an input of an average distance from projection to projection and an average distance from projections to the inner and outer peripheries (according to step S12 of FIG. 1), the pattern generation of steps S13 to S19 of FIG. 1 is executed.

Subsequently, post processing is conducted, including a step S21 of exporting the geometry of the generated projection pattern. The projection map created with the method 100 is output to a control unit of a manufacturing machine. Furthermore, the planarity of the projection pattern may be evaluated. Finally, the projection pattern is manufactured with step S22, employing a manufacturing machine using a bottom-up process or a top-down process, as it is known per se in prior art.

The features of the invention disclosed in the above description, the drawings and the claims can be of significance both individually as well as in combination or sub-combination for the realization of the invention in its various embodiments. The invention is not restricted to the preferred embodiments described above. Rather a plurality of variants and derivatives is possible which also use the inventive concept and therefore fall within the scope of protection. In addition, the invention also claims protection for the subject and features of the subclaims independently of the features and claims to which they refer.

1.-15. (canceled)

16. A method of generating a projection pattern of a plurality of projections of a substrate table configured for supporting a substrate in a surface portion of the substrate table, wherein end faces of the projections define a support plane and the surface portion is surrounded by a plurality of outer periphery points within the support plane, the method comprising:
providing a plurality of two-dimensional repulsive periphery potentials acting in the support plane, wherein the periphery potentials comprise outer periphery potentials, each being assigned to one of the outer periphery points and represented by an outer periphery potential function f₀(r₀), with r₀ being a radial distance from the outer periphery point;
providing an initial distribution of a plurality of projections, each having a variable projection position in the surface portion;
providing a plurality of two-dimensional repulsive projection potentials acting in the support plane, wherein each of the projection potentials is assigned to one of the projections and wherein, for each of the projections, the assigned projection potential is represented by a projection potential function fₚ(rₚ), with rp being a radial distance from the projection;
calculating, by a hardware computer system, a local force acting on each of the projections, wherein each local force is calculated based on a superposition of the periphery potential and the projection potential at the projection position of the respective projection; and
generating the projection pattern to be obtained by repeatedly step-wise shifting the projection positions by position shifting increments and calculating the local force acting on each of the projections at the current projection position, until a predetermined optimization criterion is fulfilled.

17. The method according to claim 16, wherein each of the outer periphery points is represented by an outer periphery projection with a fixed position.

18. The method according to claim 16, wherein:
the surface portion includes at least one inner functional element surrounded by a plurality of inner periphery points, and
the periphery potentials further comprise inner periphery potentials, each being assigned to one of the inner periphery points and represented by an inner periphery potential function fᵢ(rᵢ), with rᵢ being a radial distance from the inner periphery point.

19. The method according to claim 18, wherein each of the inner periphery points is represented by an inner periphery projection with a fixed position.

20. The method according to claim 18, wherein the at least one inner functional element comprises at least one selected from: a dot shaped gap, a line shaped gap and/or an area shaped gap in the arrangement of projections.

21. The method according to claim 16, wherein the local force acting on each projection is determined by a linear superposition of the periphery potentials and the projection potentials at the projection position of the projection, and/or
wherein the optimization criterion is determined by a sum of the local forces acting on the projections and the shifting the projection positions is executed until the projection pattern is created, at which the sum of the local forces acting on the projections is minimized, and/or
wherein the optimization criterion is determined by a sum of all current position shifting increments, and the shifting the projection positions is executed until the sum of all current position shifting increments is below a predetermined threshold.

22. The method according to claim 16, further comprising analyzing a convergence of the projection positions by a statistical analysis of averaged distances of the projections and a variance of the averaged distances of the projections.

23. The method according to claim 22, wherein the position shifting increment is adjusted in dependence of the convergence of the projection positions.

24. The method according to claim 16, wherein the periphery potentials and the projection potentials are represented by potential functions proportional to 1/r^{p}, with p being an uneven number in a range from 1 to 11.

25. The method according to claim 16, further comprising changing the number of projections during the step-wise shifting the projection positions.

26. A method of manufacturing a substrate table configured for holding a substrate, the method comprising:
creating a projection pattern of projection positions of projections of the substrate table with the method according to claim 16; and
manufacturing the projections on the substrate table at the positions provided by the projection pattern.

27. A substrate table configured for holding a substrate, the substrate table comprising a plurality of projections, wherein end faces of the projections define a support plane for holding the substrate in a surface portion of the substrate table, wherein the projections are arranged according to a projection pattern of projection positions, which is generated by the method according to claim 16.

28. The substrate table according to claim 27, wherein the projection pattern of most of the projections is matched to a hexagonal pattern.

29. An apparatus for data processing, comprising a computer device configured to execute the method according to claim 16.

30. A non-transitory computer program product comprising instructions therein, the instructions, when executed by a computer system, configured to cause the computer system to at least:
provide a plurality of two-dimensional repulsive periphery potentials acting in a support plane to be defined by end faces of projections of a substrate table configured for supporting a substrate in a surface portion of the substrate table, wherein the surface portion is surrounded by a plurality of outer periphery points within the support plane and wherein the periphery potentials comprise outer periphery potentials, each being assigned to one of the outer periphery points;
provide an initial distribution of a plurality of projections, each having a variable projection position in the surface portion;
provide a plurality of two-dimensional repulsive projection potentials acting in the support plane, wherein each of the projection potentials is assigned to one of the projections;
calculate a local force acting on each of the projections, wherein each local force is calculated based on a superposition of the periphery potential and the projection potential at the projection position of the respective projection; and
generate a projection pattern of the plurality of projections to be obtained by repeated step-wise shift of the projection positions by position shifting increments and calculation of the local force acting on each of the projections at the current projection position, until a predetermined optimization criterion is fulfilled.

31. The computer program product of claim 30, wherein, for each of the outer periphery points, the assigned outer periphery potential is represented by an outer periphery potential function f₀(r₀), with r₀ being a radial distance from the outer periphery point, and wherein, for each of the projections, the assigned projection potential is represented by a projection potential function fₚ(rₚ), with rp being a radial distance from the projection.

32. The computer program product of claim 30, wherein each of the outer periphery points is represented by an outer periphery projection with a fixed position.

33. The computer program product of claim 30, wherein:
the surface portion includes at least one inner functional element surrounded by a plurality of inner periphery points, and
the periphery potentials further comprise inner periphery potentials, each being assigned to one of the inner periphery points.

34. The computer program product of claim 30, wherein the local force acting on each projection is determined by a linear superposition of the periphery potentials and the projection potentials at the projection position of the projection, and/or
wherein the optimization criterion is determined by a sum of the local forces acting on the projections and the shift of the projection positions is executed until the projection pattern is created, at which the sum of the local forces acting on the projections is minimized, and/or
wherein the optimization criterion is determined by a sum of all current position shifting increments, and the shift of the projection positions is executed until the sum of all current position shifting increments is below a predetermined threshold.

35. The computer program product of claim 30, wherein the instructions are further configured to cause the computer system to analyze a convergence of the projection positions by a statistical analysis of averaged distances of the projections and a variance of the averaged distances of the projections.
